(19) United States
(12) Patent Application Publication
(10) Pub. No.: US 2007/0023925 A1
(43) Pub. Date: Feb. 1, 2007

(54) Semiconductor element with conductive bumps and fabrication method thereof

(75) Inventors: Chun-Chi Ke, Taichung Hsien (TW); Kook-Jui Tai, Taichung (TW); Chien-Ping Huang, Hsinchu Hsein (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/414,275

(22) Filed: Apr. 27, 2006

(30) Foreign Application Priority Data
Jul. 26, 2005 (TW) 094125224

(51) Int. Cl. H01L 21/00; H01L 21/44; H01L 23/48

(52) U.S. Cl. 257/779; 438/118; 438/612; 257/787

(57) ABSTRACT

A semiconductor device and a fabrication method thereof are provided. A first passivation layer and a second passivation layer are applied on a semiconductor substrate having at least one bond pad, with the bond pad being exposed. A first metallic layer is formed on the second passivation layer and electrically connected to the bond pad. A third passivation layer is applied on the first metallic layer and exposes a portion of the first metallic layer. A second metallic layer is formed on the third passivation layer and electrically connected to the exposed portion of the first metallic layer. A fourth passivation layer is applied on the second metallic layer and has an opening corresponding in position to the bond pad, allowing a portion of the second metallic layer to be exposed via the opening, such that a solder bump is formed on the exposed portion of the second metallic layer.

### FIELD OF THE INVENTION

The present invention relates to semiconductor devices and fabrication methods thereof, and more particularly, to a semiconductor device with solder bumps and a fabrication method of the semiconductor device.

### BACKGROUND OF THE INVENTION

The progress of semiconductor packaging technology and the improvement in circuit functionality of chips contribute to the development of semiconductor devices with reduced integrated circuit (IC) area and increased input/output (I/O) connections, such as ball grid array (BGA) package, flip-chip package, chip size package (CSP) and so on, which are suitably applied to various portable electronic devices in the fields of communications, networks and computers.

For a flip-chip semiconductor package, a semiconductor substrate such as a wafer or chip is first implanted with solder bumps on contacts (such as bond pads) thereof, and then is electrically connected to a carrier such as an organic substrate directly via the solder bumps. Compared to conventional wire-bonding technology, the flip-chip semiconductor package is advantageous of having a shorter circuit path and better electrical performance. A further advantage of the flip-chip semiconductor package is that a back side of the chip can be exposed so as to improve the heat dissipating efficiency thereof. Therefore, flip-chip packaging technology is widely used in the semiconductor package industry.

Generally, before implanting the solder bumps on the wafer or chip, an under bump metallurgy (UBM) structure is formed on the bond pads of the wafer or chip, so as to allow the subsequent solder bumps to be firmly bonded to the wafer or chip by means of the UBM structure. The related prior arts include U.S. Pat. Nos. 6,111,321; 6,229,220; 6,107,180; and 6,586,323. However, when the wafer or chip is electrically connected to the substrate directly via the solder bumps, thermal stress is generated due to mismatch in coefficient of thermal expansion (CTE) between the wafer/chip and the substrate. The thermal stress concentrates on the solder bumps and the UBM structure, such that cracking or delamination of the solder bumps and the UBM structure may easily occur, thereby adversely affecting the electrical performance and reliability of the semiconductor package.

In light of the aforementioned problem, an underfilling process is implemented to fill a gap between the chip and the substrate with an underfill material in the flip-chip semiconductor package so as to alleviate or relieve the thermal stress exerted to the solder bumps and the UBM structure. The related prior arts include U.S. Pat. Nos. 5,720,100; 6,074,895; and 6,372,544. However, the underfilling process is time-ineffective to implement and cannot be reworked as well as has a problem of adaptability of the underfill material.

Another approach to the cracking and delamination problem is a re-passivation process, which applies a dielectric layer (such as benzo-cyclo-butene (BCB) or polyimide) on the wafer or chip before forming the UBM structure. The dielectric layer is used to absorb the thermal stress exerted to the solder bumps and the UBM structure, such that cracking or delamination of the solder bumps and the UBM structure can be reduced. The re-passivation process is illustrated with reference to FIGS. 1A to 1E.

Firstly, as shown in FIG. 1A, a semiconductor substrate 10 having at least one bond pad (I/O contact) 11 is provided, and a passivation layer 12 is applied on the semiconductor substrate 10, wherein the bond pad 11 is exposed from the passivation layer 12. Next, as shown in FIG. 1B, a dielectric layer 13, which is made of such as polyimide or BCB, is formed on the passivation layer 12, wherein the bond pad 11 is exposed from the dielectric layer 13. As shown in FIG. 1C, a UBM structure 14 is formed on the bond pad 11 by a sputtering or plating technique. Then, as shown in FIG. 1D, a solder mask layer 15 is formed on the dielectric layer 13, without covering the UBM structure 14, and solder 16 is applied on the UBM structure 14. Finally, after in turn performing a first reflow process on the solder 16, removing the solder mask layer 15, and performing a second reflow process on the solder 16, a solder bump 17 as shown in FIG. 1E is formed on the UBM structure 14. The dielectric layer 13 disposed between the UBM structure 14 and the passivation layer 12 is used to absorb the thermal stress exerted to the UBM structure 14 and the solder bump 17.

In the case of having a reduced pitch width between adjacent metallic circuits of the chip (such as smaller than 90 nm or even reduced to 65 nm, 45 nm or 32 nm), a dielectric material with a low dielectric constant (low k) should be introduced to overcome resistance-capacity (RC) time delay caused by the reduced pitch width and allow the metallic circuits (not shown) of the chip to be closely arranged, such that signal leakage and interference can be prevented and the transmission speed can be improved. However, the dielectric material with the low k is relatively rigid and fragile, thereby easily leading to delamination or crack of the dielectric layer. Moreover, as the thermal stress is primarily exerted to an interface between the solder bump 17 and the UBM structure 14, the dielectric layer (not shown) formed under the UBM structure 14 will be more easily delaminated or cracked because the re-passivated dielectric layer can only relieve a portion of the thermal stress in a lateral direction and fails to provide a sufficient buffer effect to offset the thermal stress, such that the problem of cracking of the solder bump 17 or delamination of the UBM structure 14 is still not properly solved.

Therefore, the problem to be solved here is to provide a semiconductor device and a fabrication method thereof so as to overcome the foregoing drawbacks in the prior art.

### SUMMARY OF THE INVENTION

In light of the above-mentioned drawbacks in the prior art, it is a primary objective of the present invention to provide a semiconductor device and a fabrication method thereof, for reducing thermal stress exerted to low k layers of the semiconductor device.

It is another objective of the present invention to provide a semiconductor device and a fabrication method thereof, for preventing cracking or delamination of the solder bumps and UBM structure of the semiconductor device.

It is a further objective of the present invention to provide a semiconductor device and a fabrication method thereof, applicable to a wafer or chip with low dielectric constant layers.

To achieve the foregoing and other objectives, the present invention proposes a semiconductor device according to a first preferred embodiment, comprising: a semiconductor substrate having at least one bond pad; a first passivation layer applied on the semiconductor substrate and having an opening for exposing the bond pad; a second passivation layer applied on the first passivation layer, allowing the bond pad to be exposed from the second passivation layer; a first metallic layer formed on the second passivation layer and electrically connected to the bond pad exposed from the second passivation layer; a third passivation layer applied on the first metallic layer and the second passivation layer, allowing a portion of the first metallic layer to be exposed from the third passivation layer; a second metallic layer formed on the third passivation layer and electrically connected to the exposed portion of the first metallic layer; a fourth passivation layer applied on the second metallic layer and the third passivation layer, and formed with an opening corresponding in position to the bond pad such that a portion of the second metallic layer is exposed via the opening of the fourth passivation layer; and a solder bump electrically connected to the portion of the second metallic layer exposed via the opening of the fourth passivation layer.

The present invention proposes another semiconductor device according to a second preferred embodiment, comprising: a semiconductor substrate having at least one bond pad; a first passivation layer applied on the semiconductor substrate and having an opening for exposing the bond pad; a second passivation layer applied on the first passivation layer, allowing the bond pad to be exposed from the second passivation layer; a first metallic layer formed on the second passivation layer and electrically connected to the bond pad exposed from the second passivation layer; a third passivation layer applied on the first metallic layer and the second passivation layer, allowing a portion of the first metallic layer to be exposed from the third passivation layer; a second metallic layer formed on the third passivation layer and electrically connected to the exposed portion of the first metallic layer; a fourth passivation layer applied on the second metallic layer and the third passivation layer, and formed with an opening corresponding in position to the bond pad such that a portion of the second metallic layer is exposed via the opening of the fourth passivation layer; a third metallic layer formed at the opening of the fourth passivation layer and electrically connected to the portion of the second metallic layer exposed via the opening of the fourth passivation layer; and a solder bump electrically connected to the third metallic layer at the opening of the fourth passivation layer.

The semiconductor substrate can be a semiconductor chip or a wafer. The first passivation layer can be a silicon nitride layer. Each of the second and third passivation layers can be a dielectric layer made of benzo-cyclo-butene (BCB) or polyimide. The fourth passivation layer can be a dielectric layer or a solder mask layer. The third metallic layer can be an under bump metallurgy (UBM) structure comprising, for example, layers of aluminum, nickel-vanadium alloy, copper and/or titanium. Each of the first and second metallic layers can be a re-distribution layer made of, for example, aluminum, nickel-vanadium alloy, copper or titanium.

The present invention proposes a fabrication method of the semiconductor device according to the first preferred embodiment, comprising the steps of: applying a first passivation layer on a semiconductor substrate having at least one bond pad, the first passivation layer having an opening for exposing the bond pad, and applying a second passivation layer on the first passivation layer, with the bond pad being exposed from the second passivation layer; forming a first metallic layer on the second passivation layer, and allowing the first metallic layer to be electrically connected to the bond pad exposed from the second passivation layer; applying a third passivation layer on the first metallic layer and the second passivation layer, with a portion of the first metallic layer being exposed from the third passivation layer; forming a second metallic layer on the third passivation layer, and allowing the second metallic layer to be electrically connected to the exposed portion of the first metallic layer; applying a fourth passivation layer on the second metallic layer and the third passivation layer, and forming an opening in the fourth passivation layer at a position corresponding to the bond pad such that a portion of the second metallic layer is exposed via the opening of the fourth passivation layer; and forming a solder bump on the portion of the second metallic layer exposed via the opening of the fourth passivation layer.

The present invention also proposes a fabrication method of the semiconductor device according to the second preferred embodiment, comprising the steps of: applying a first passivation layer on a semiconductor substrate having at least one bond pad, the first passivation layer having an opening for exposing the bond pad, and applying a second passivation layer on the first passivation layer, with the bond pad being exposed from the second passivation layer; forming a first metallic layer on the second passivation layer, and allowing the first metallic layer to be electrically connected to the bond pad exposed from the second passivation layer; applying a third passivation layer on the first metallic layer and the second passivation layer, with a portion of the first metallic layer being exposed from the third passivation layer; forming a second metallic layer on the third passivation layer, and allowing the second metallic layer to be electrically connected to the exposed portion of the first metallic layer; applying a fourth passivation layer on the second metallic layer and the third passivation layer, and forming an opening in the fourth passivation layer at a position corresponding to the bond pad such that a portion of the second metallic layer is exposed via the opening of the fourth passivation layer; forming a third metallic layer at the opening of the fourth passivation layer, and allowing the third metallic layer to be electrically connected to the portion of the second metallic layer exposed via the opening of the fourth passivation layer; and forming a solder bump on the third metallic layer at the opening of the fourth passivation layer.

Therefore, the semiconductor device and the fabrication method thereof in the present invention provide a plurality of passivation layers and metallic layers on a bond pad of a semiconductor substrate, allow the metallic layers to be electrically connected to the bond pad, and form an outmost passivation layer having an opening on the plurality of metallic layers, wherein the opening of the outmost passivation layer corresponds in position to the bond pad, such that a solder bump is bonded to the metallic layer exposed via the opening of the outmost passivation layer. The plurality of passivation layers disposed under the solder bump can provide a satisfactory buffer effect for absorbing or reducing thermal stress exerted to the solder bump and the metallic layers thereunder, thereby eliminating the prior-art problems such as cracking of solder bump and UBM structure and delamination of dielectric layer with low dielectric constant.

### BRIEF DESCRIPTION OF THE DRAWINGS

The present invention can be more fully understood by reading the following detailed description of the preferred embodiments, with reference made to the accompanying drawings, wherein:

FIGS. 1A to 1E (PRIOR ART) are schematic cross-sectional diagrams showing steps of a conventional method for fabricating a semiconductor device;

FIGS. 2A to 2G are schematic cross-sectional diagrams showing steps of a fabrication method of a semiconductor device according to a first preferred embodiment of the present invention; and

FIGS. 3A to 3H are schematic cross-sectional diagrams showing steps of a fabrication method of a semiconductor device according to a second preferred embodiment of the present invention.

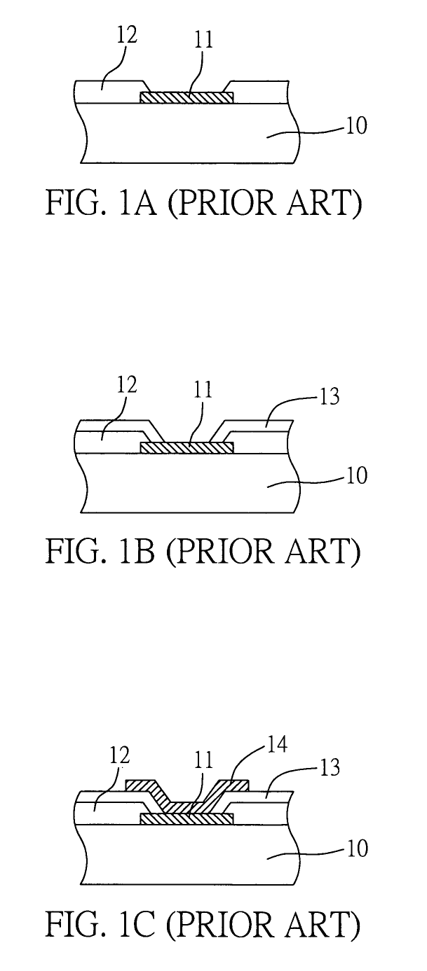

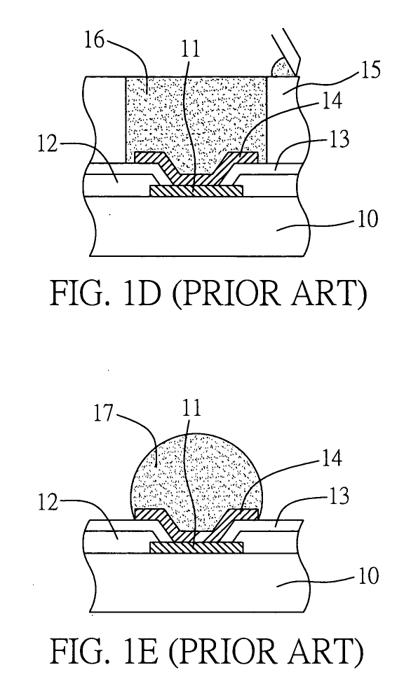

### DETAILED DESCRIPTION OF THE PREFERRED EMBODIMENTS

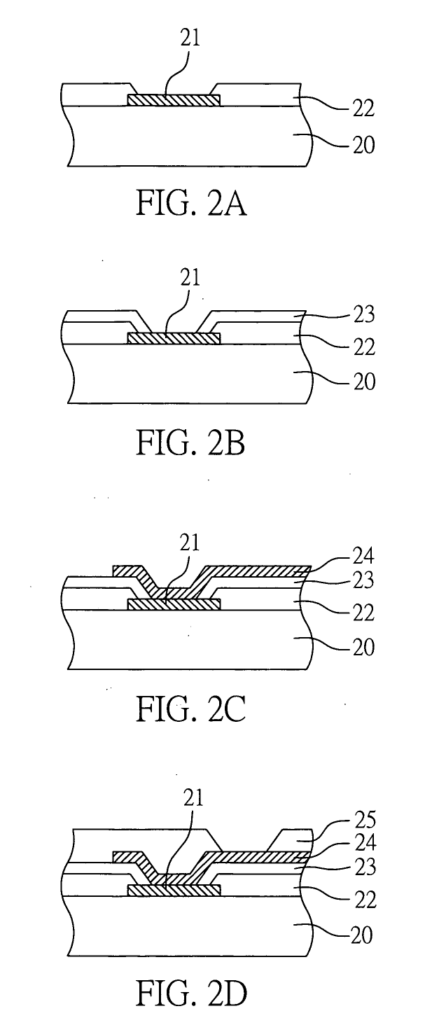

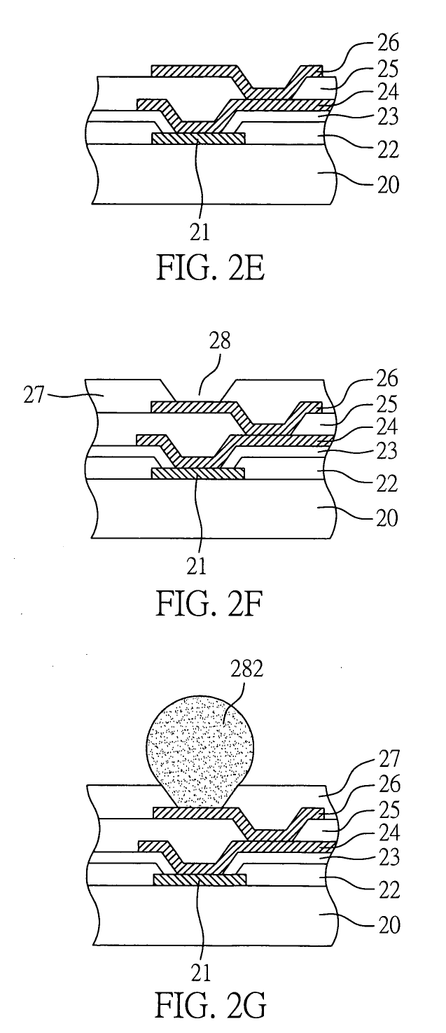

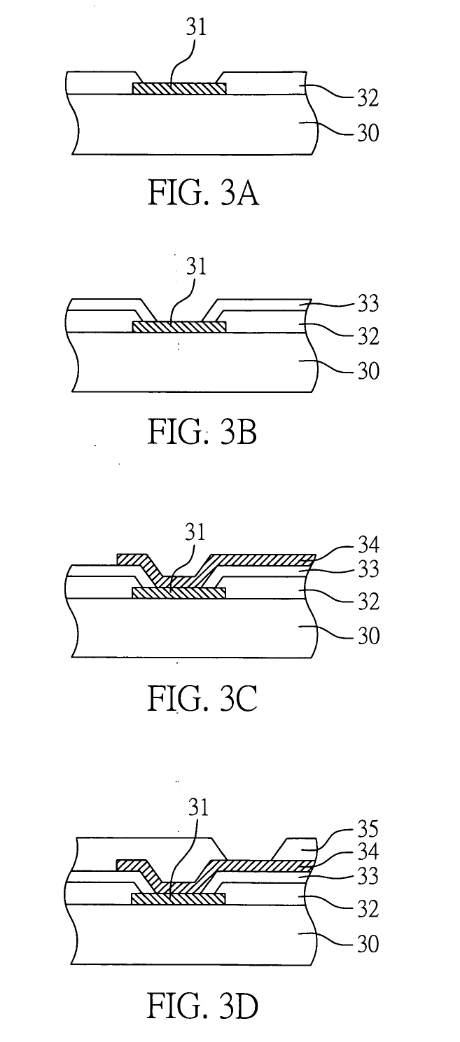

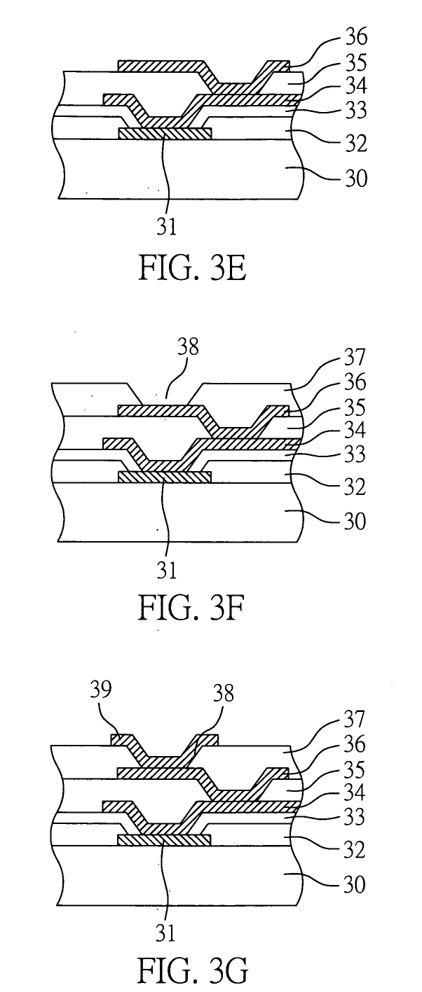

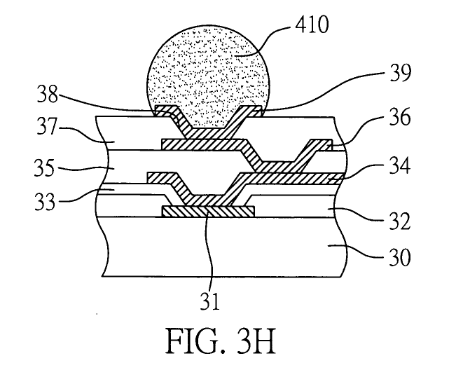

Preferred embodiments of a semiconductor device and a fabrication method thereof proposed in the present invention are described as follows with reference to FIGS. 2A to 2G and 3A to 3H, which do not set a limitation on the scope of the present invention.

### First Preferred Embodiment

Referring to FIG. 2G, a semiconductor device according to a first preferred embodiment of the present invention comprises a semiconductor substrate 20, a first passivation layer 22, a second passivation layer 23, a first metallic layer 24, a third passivation layer 25, a second metallic layer 26, a fourth passivation layer 27 and a solder bump 282.

The semiconductor substrate 20 can be a semiconductor chip or a wafer comprising a plurality of chip units, having low dielectric constant (low k) layers. At least one bond pad 21 is formed on an active surface of the semiconductor substrate 20. The first passivation layer 22 is applied on the active surface of the semiconductor substrate 20 and has an opening for at least partly exposing the bond pad 21. The first passivation layer 22 can be a silicon nitride layer and is used to protect the semiconductor substrate 20 and partly the bond pad 21.

The second passivation layer 23 is applied on the first passivation layer 22, wherein the bond pad 21 is exposed from the second passivation layer 23. The second passivation layer 23 can be made of benzo-cyclo-butene (BCB), polyimide or the like.

The first metallic layer 24 is formed on the second passivation layer 23 and is electrically connected to the bond pad 21 exposed from second passivation layer 23. The first metallic layer 24 can be a re-distribution layer (RDL) made of, but not limited to, aluminum, nickel-vanadium alloy, copper or titanium.

The third passivation layer 25 is applied on the first metallic layer 24 and the second passivation layer 23, wherein a portion of the first metallic layer 24 is exposed from the third passivation layer 25. The third passivation layer 25 can be made of BCB, polyimide or the like, and is used to protect the first metallic layer 24.

The second metallic layer 26 is formed on the third passivation layer 25 and is electrically connected to the exposed portion of the first metallic layer 24. The second metallic layer 26 can be a re-distribution layer (RDL) made of, but not limited to, aluminum, nickel-vanadium alloy, copper or titanium.

The fourth passivation layer 27 is applied on the second metallic layer 26 and the third passivation layer 25. The fourth passivation layer 27 is formed with an opening corresponding in position to the bond pad 21, allowing a portion of the second metallic layer 26 to be exposed via the opening of the fourth passivation layer 27, wherein a central position of the opening of the fourth passivation layer 27 substantially corresponds to a central position of the bond pad 21. The fourth passivation layer 27 can be a dielectric layer or a solder mask layer.

The solder bump 282 is bonded and electrically connected to the portion of the second metallic layer 26 exposed via the opening of the fourth passivation layer 27. The solder bump 282 can be made of tin-lead alloy.

Therefore, the semiconductor device in the present invention provides a plurality of passivation layers and metallic layers on a bond pad of a semiconductor substrate, allows the metallic layers to be electrically connected to the bond pad, and forms an outmost passivation layer having an opening on the plurality of metallic layers, wherein the opening of the outmost passivation layer corresponds in position to the bond pad, such that a solder bump is bonded to the metallic layer exposed via the opening of the outmost passivation layer. The plurality of passivation layers disposed under the solder bump can provide a satisfactory buffer effect for absorbing or reducing thermal stress exerted to the solder bump and the metallic layers thereunder, thereby eliminating the prior-art problems such as cracking of solder bump and UBM structure and delamination of dielectric layers with low dielectric constant.

The above semiconductor device can be fabricated by a method comprising the steps shown in FIGS. 2A to 2G.

Firstly, as shown in FIG. 2A, a semiconductor substrate 20 having at least one bond pad 21 on a surface thereof is provided. The semiconductor substrate 20 can be a semiconductor chip or a wafer comprising a plurality of chip units, having low dielectric constant (low k) layers. A first passivation layer 22 is formed on the surface of the semiconductor substrate 20 and has an opening for at least partly exposing the bond pad 21. The first passivation layer 22 can be made of nitride (such as silicon nitride) and is used to protect the semiconductor substrate 20 and partly the bond pad 21.

As shown in FIG. 2B, a second passivation layer 23 is formed on the first passivation layer 22, allowing the bond pad 21 to be exposed from the second passivation layer 23. The second passivation layer 23 can be made of BCB, polyimide or the like. In the foregoing and following steps, conventional techniques such as etching, deposition, patterning and so on may be used for example to expose the bond pad 21 from the second passivation layer 23, which are well known in the art and thus not to be further detailed in the description here.

As shown in FIG. 2C, a first metallic layer 24 is formed on the second passivation layer 23 and is electrically connected to the bond pad 21 exposed from the second passivation layer 23. The first metallic layer 24 can be a re-distribution layer made of, but not limited to, aluminum, nickel-vanadium alloy, copper or titanium.

As shown in FIG. 2D, a third passivation layer 25 is applied on the second passivation layer 23 and the first metallic layer 24, allowing a portion of the first metallic layer 24 to be exposed from the third passivation layer 25. The third passivation layer 25 can be made of BCB or polyimide.

Next, as shown in FIG. 2E, a second metallic layer 26 is formed on the third passivation layer 25 and is electrically connected to the exposed portion of the first metallic layer 24. The second metallic layer 26 can be a re-distribution layer made of, but not limited to, aluminum, nickel-vanadium alloy, copper or titanium.

Then, as shown in FIG. 2F, a fourth passivation layer 27 is applied on the second metallic layer 26 and the third passivation layer 25. The fourth passivation layer 27 is formed with an opening 28 corresponding in position to the bond pad 21, allowing a portion of the second metallic layer 26 to be exposed via the opening 28 of the fourth passivation layer 27. The fourth passivation layer 27 can be a dielectric layer or a solder mask layer.

Finally, as shown in FIG. 2G, a printing and reflow process or a plating and reflow process is performed to form a solder bump 282 on the portion of the second metallic layer 26 exposed via the opening 28 of the fourth passivation layer 27.

### Second Preferred Embodiment

Referring to FIG. 3H, a semiconductor device according to a second preferred embodiment of the present invention comprises a semiconductor substrate 30 having at least on bond pad 31, a first passivation layer 32, a second passivation layer 33, a first metallic layer 34, a third passivation layer 35, a second metallic layer 36, a fourth passivation layer 37, a third metallic layer 39 and a solder bump 410. The semiconductor device of the second embodiment is structurally similar to that of the above first embodiment, except that the third metallic layer 39 is additionally formed on the fourth passivation layer 37 and serves as a UBM structure for bonding the solder bump 410 in the second embodiment.

In this embodiment, the solder bump 410 is located corresponding in position to the bond pad 31, such that the second, third and fourth passivation layers 33, 35, 37 disposed between the solder bump 410 and the bond pad 31 can provide a satisfactory buffer effect for reducing thermal stress exerted to the solder bump 410, thereby eliminating problems such as cracking of solder bump or delamination of UBM structure, and allowing the chip or wafer with the low dielectric constant layers to be suitably used in the present invention.

The semiconductor device according to the second embodiment can be fabricated by a method comprising the steps shown in FIGS. 3A to 3H. In the second embodiment, the techniques and materials being used, which are same as those in the first embodiment, are not to be repeated hereinafter.

Firstly, as shown in FIG. 3A, a semiconductor substrate 30 having at least one bond pad 31 on a surface thereof is provided. A first passivation layer 32 is formed on the surface of the semiconductor substrate 30 and has an opening for at least partly exposing the bond pad 31.

As shown in FIG. 3B, a second passivation layer 33 is formed on the first passivation layer 32, allowing the bond pad 31 to be exposed from the second passivation layer 33.

As shown in FIG. 3C, a first metallic layer 34 is formed on the second passivation layer 33 and is electrically connected to the bond pad 31 exposed from the second passivation layer 33.

As shown in FIG. 3D, a third passivation layer 35 is applied on the second passivation layer 33 and the first metallic layer 34, allowing a portion of the first metallic layer 34 to be exposed from the third passivation layer 35.

Next, as shown in FIG. 3E, a second metallic layer 36 is formed on the third passivation layer 35 and is electrically connected to the portion of the first metallic layer 34 exposed from the third passivation layer 35.

Then, as shown in FIG. 3F, a fourth passivation layer 37 is applied on the second metallic layer 36 and the third passivation layer 35. The fourth passivation layer 37 is formed with an opening 38 corresponding in position to the bond pad 31, allowing a portion of the second metallic layer 36 to be exposed via the opening 38 of the fourth passivation layer 37.

As shown in FIG. 3G, a third metallic layer 39 is formed on the portion of the second metallic layer 36 exposed via the opening 38 of the fourth passivation layer 37 and is electrically connected to the second metallic layer 36. The third metallic layer 39 is a UBM structure for bonding a solder bump formed subsequently.

Finally, as shown in FIG. 3H, a printing and reflow process or a plating and reflow process is performed to form a solder bump 410 on the third metallic layer 39 at the opening 38 of the fourth passivation layer 37.

Therefore, the semiconductor device and the fabrication method thereof in the present invention provide a plurality of passivation layers and metallic layers on a bond pad of a semiconductor substrate, allow the metallic layers to be electrically connected to the bond pad, and form an outmost passivation layer having an opening on the plurality of metallic layers, wherein the opening of the outmost passivation layer corresponds in position to the bond pad, such that a solder bump is bonded to the metallic layer exposed via the opening of the outmost passivation layer. The plurality of passivation layers disposed under the solder bump can provide a satisfactory buffer effect for absorbing or reducing thermal stress exerted to the solder bump and the metallic layers thereunder, thereby eliminating problems such as cracking of solder bump and UBM structure and delamination of dielectric layers with low dielectric constant. Thus, the semiconductor device and the fabrication method thereof in the present invention can overcome the drawbacks of the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor device comprising:
a semiconductor substrate having at least one bond pad;
a first passivation layer applied on the semiconductor substrate and having an opening for exposing the bond pad;
a second passivation layer applied on the first passivation layer, allowing the bond pad to be exposed from the second passivation layer;
a first metallic layer formed on the second passivation layer and electrically connected to the bond pad exposed from the second passivation layer;
a third passivation layer applied on the first metallic layer and the second passivation layer, allowing a portion of the first metallic layer to be exposed from the third passivation layer;
a second metallic layer formed on the third passivation layer and electrically connected to the exposed portion of the first metallic layer;
a fourth passivation layer applied on the second metallic layer and the third passivation layer, and formed with an opening corresponding in position to the bond pad, allowing a portion of the second metallic layer to be exposed via the opening of the fourth passivation layer; and
a solder bump bonded and electrically connected to the portion of the second metallic layer exposed via the opening of the fourth passivation layer.

2. The semiconductor device of claim 1, wherein a central position of the opening of the fourth passivation layer corresponds to a central position of the bond pad.

3. The semiconductor device of claim 1, further comprising a third metallic layer formed at the opening of the fourth passivation layer and electrically connected to the portion of the second metallic layer exposed via the opening of the fourth passivation layer, such that the solder bump is formed on the third metallic layer.

4. The semiconductor device of claim 3, wherein the third metallic layer is an under bump metallurgy (UBM) structure.

5. The semiconductor device of claim 1, wherein the semiconductor substrate is one of a semiconductor chip with low dielectric constant layers and a wafer with low dielectric constant layers.

6. The semiconductor device of claim 1, wherein the first passivation layer is a silicon nitride layer.

7. The semiconductor device of claim 1, wherein each of the second and third passivation layers is made of one of benzo-cyclo-butene (BCB) and polyimide.

8. The semiconductor device of claim 1, wherein the fourth passivation layer is one of a dielectric layer and a solder mask layer.

9. The semiconductor device of claim 8, wherein the dielectric layer is made of one of BCB and polyimide.

10. The semiconductor device of claim 1, wherein each of the first and second metallic layers is a re-distribution layer (RDL).

11. A fabrication method of a semiconductor device, comprising the steps of:
applying a first passivation layer on a semiconductor substrate having at least one bond pad, the first passivation layer having an opening for exposing the bond pad, and applying a second passivation layer on the first passivation layer, with the bond pad being exposed from the second passivation layer;
forming a first metallic layer on the second passivation layer, and allowing the first metallic layer to be electrically connected to the bond pad exposed from the second passivation layer;
applying a third passivation layer on the first metallic layer and the second passivation layer, with a portion of the first metallic layer being exposed from the third passivation layer;
forming a second metallic layer on the third passivation layer, and allowing the second metallic layer to be electrically connected to the exposed portion of the first metallic layer;
applying a fourth passivation layer on the second metallic layer and the third passivation layer, and forming an opening in the fourth passivation layer at a position corresponding to the bond pad such that a portion of the second metallic layer is exposed via the opening of the fourth passivation layer; and
forming a solder bump on the portion of the second metallic layer exposed via the opening of the fourth passivation layer.

12. The fabrication method of claim 11, wherein a central position of the opening of the fourth passivation layer corresponds to a central position of the bond pad.

13. The fabrication method of claim 11, further comprising a step of forming a third metallic layer at the opening of the fourth passivation layer and allowing the third metallic layer to be electrically connected- to the portion of the second metallic layer exposed via the opening of the fourth passivation layer, such that the solder bump is formed on the third metallic layer.

14. The fabrication method of claim 13, wherein the third metallic layer is an under bump metallurgy (UBM) structure.

15. The fabrication method of claim 11, wherein the semiconductor substrate is one of a semiconductor chip with low dielectric constant layers and a wafer with low dielectric constant layers.

16. The fabrication method of claim 11, wherein the first passivation layer is a silicon nitride layer.

17. The fabrication method of claim 11, wherein each of the second and third passivation layers is made of one of benzo-cyclo-butene (BCB) and polyimide.

18. The fabrication method of claim 11, wherein the fourth passivation layer is one of a dielectric layer and a solder mask layer.

19. The fabrication method of claim 18, wherein the dielectric layer is made of one of BCB and polyimide.

20. The fabrication method of claim 11, wherein each of the first and second metallic layers is a re-distribution layer (RDL).
